(19) United States
(12) Patent Application Publication
(10) Pub. No.: US 2010/0126580 A1
(43) Pub. Date: May 27, 2010

(54) CdTe deposition process for solar cells

(76) Inventors: James F. Farrell, Toronto (CA); Hehong Zhao, Los Altos, CA (US)

Correspondence Address: WOODSIDE IP GROUP, P.O. BOX 61047, PALO ALTO, CA, 94306, US

(21) Appl. No.: 12/592,383

(22) Filed: Nov. 23, 2009

Related U.S. Application Data
(60) Provisional application No. 61/200,235, filed on Nov. 26, 2008.

(51) Int. Cl. H01L 31/0296; H01L 31/18

(52) U.S. Cl. 136/256; 438/95; 257/E31.015

(57) ABSTRACT

An inexpensive system is provided for manufacturing a CdTe solar cell in a single pass using sputtering without the need for a wet process and without the need for high temperature gas diffusion. Thus, toxic gases and wet chemical baths are advantageously eliminated. A halogen gas, such as chlorine, and oxygen are added during the sputtering of a CdTe film, so that a wet process is eliminated and the deposited CdTe film can be annealed rapidly, such as by a rapid thermal anneal process (RTA).

### CROSS REFERENCE TO RELATED APPLICATION

This application claims the benefit of U.S. provisional application Ser. No. 61/200,235, filed Nov. 26, 2008.

### BACKGROUND

1. Field of the Invention

The field of the invention relates generally to semiconductor thin film deposition for photovoltaic applications. In particular, the field of the invention relates to a system and method for using a halogen sputter gas for increasing the deposition rate of a cadmium telluride (CdTe) thin film, such that the carrier lifetime of the CdTe layer can be increased and composition of the CdTe film can be adjusted and altered by the sputter gas composition without the need for a subsequent wet process step. This process improves the electronic properties of the film.

2. Background of Related Art

CdTe and CdS are well known materials for use in solar cells. CdTe is a direct bandgap material that is optimal for absorbing the solar energy spectrum. The bandgap of CdTe is 1.5 eV at room temperature. The maximum theoretical efficiency of a CdTe thin film is believed to be about 27 percent. A CdTe layer of only a few microns in thickness absorbs more than 90 percent of light having photon energy above the bandgap with a high absorption coefficient, greater than 10⁵ cm⁻¹, at a wavelength of 700 nm. Determination of the absorption coefficient in CdTe solar cells is important since the optimum layer thickness for high efficiency devices depends on this parameter. The small thickness required for the energy absorbing layer makes the cost of materials for a CdTe solar cell relatively low. Thus, the development of new processing techniques for high efficiency CdTe cells may be critical to lowering the cost of producing solar energy.

It is known in the CdTe solar cell field that a CdCl₂treatment is necessary in order to make efficient solar cells. A conventional method for making a thin film photovoltaic device provides a deposition of the CdTe film, and then immerses the substrate to soak the substrate in the solution of CdCl₂ for some period of time. The solution of CdCl₂ causes chlorine to be absorbed by the CdTe film, and then subsequent annealing causes the grains to grow larger. The annealing is done in an oxygen-containing atmosphere, and the oxygen reacts with the film. The oxygen is thought to form CdO, which is dispersed throughout the film, but is preferentially located at the grain boundaries. This process thereby passivates the grain boundaries, resulting in improved efficiency solar cells. However, this conventional process is a time consuming wet process, and is not conducive to in-line processing.

Another conventional method for making a CdTe thin film solar cell comprises depositing a film of CdCl₂ on the CdTe film and then annealing the two films together. After the anneal is accomplished, the CdTe film must be etched to remove surface oxides that are formed during the annealing step. Such oxides create a p+ tellurium rich layer.

A further conventional method is to expose the CdTe film to HCl gas. This method has been investigated and found to be less effective than the CdCl₂ treatment and is not widely used. It is difficult to control the vapor concentration of HCl, however, and the cell efficiency is highly sensitive to HCl concentration. Another disadvantage is that HCl is a corrosive gas and can cause damage to metal parts of the system.

Another conventional technique uses a chemical bath deposition (CBD) process, such as CBD deposited CdTe, to co-deposit the CdCl₂ with CdTe, adding CdCl₂ to the plating bath. This conventional process is not widely used, perhaps because this would disperse the Cl throughout the film, which is not desired.

The foregoing conventional techniques vary with the manufacturer. Another well known technique for manufacturing a thin film CdTe solar cell uses a high temperature deposition technique that results in large grain size on the deposited film without a subsequent anneal. However, the CdCl₂ treatment and high temperature oxygen anneal are both still necessary to improve the properties of the film that increase the solar cell efficiency. It is thought that the anneal improves diffusion between the CdS and the CdTe, and also improves hole carrier concentration and mobility.

### SUMMARY

In order to overcome the foregoing limitations and disadvantages inherent in conventional methods for producing CdTe thin films, an aspect of the invention provides an inexpensive system and method for manufacturing a CdTe solar cell in a single pass using sputtering without the need for a wet process and without the need for high temperature gas diffusion. Thus, toxic gases and wet chemical baths are advantageously eliminated.

In another aspect of the invention chlorine and oxygen are added during the deposition process by altering the gas flow during the deposition, so that a wet process is eliminated and the deposited CdTe film can be annealed rapidly, such as by a rapid thermal anneal process (RTA).

Another aspect of the invention provides a system and method for doping a semiconductor thin film such as CdTe while it is being deposited. A preferred embodiment comprises deposition of the CdTe film through a sputtering process, that is under a controlled low-pressure atmosphere condition, thus avoiding the expense and complexity of a wet process. This and other aspects of the invention can increase the CdTe deposition rate as much as ten times over a conventional process and thus may facilitate large scale batch processing of CdTe devices.

According to another aspect of the invention, it is advantageous to add a predetermined amount of a halogen, such as chlorine bearing gas, to the controlled atmosphere to control precisely the amount of chlorine present in the chamber atmosphere. The chlorine in the atmosphere of the sputter chamber is reactive with Cd, and a small amount of Cl is thereby incorporated into the deposited film. The amount of chlorine incorporated into the film can be controlled by the partial pressure of chlorine in the chamber.

In accordance with a further aspect of the invention, the partial pressure of the chlorine in the sputter chamber can be changed selectively during the deposition process so that the doping of the film is heavier or lighter as the film grows, thus providing an additional measure of control for specific photovoltaic applications.

In accordance with another aspect of the invention, the requirement for oxygen during the anneal step advantageously may be eliminated by introducing the oxygen into the film in the deposition chamber. Oxygen in a plasma is much more reactive than molecular oxygen, so the net effect of the device anneal, (400° C., 30 minutes or longer) could be accomplished much faster, in a rapid thermal process, which is more suitable for in-line production.

With the ability to control precisely the amount of O₂, the oxide residues on the CdTe surface can be greatly suppressed, such that the need for a wet etching process can be eliminated.

### BRIEF DESCRIPTION OF THE DRAWINGS

The drawings are heuristic for clarity. The foregoing and other features, aspects and advantages of the invention will become better understood with regard to the following description, appended claims and accompanying drawings in which:

FIG. 1 is a schematic diagram showing a conventional thin film process for creating a photovoltaic thin film.

FIG. 2 is a schematic diagram showing the conventional thin film process of FIG. 1 in greater detail.

FIG. 3 is a schematic diagram showing a process for creating a photovoltaic thin film, such as a CdTe solar cell, in accordance with an aspect of the invention.

FIG. 4 is a schematic cross sectional diagram showing a photovoltaic thin film structure made in accordance with an aspect of the invention.

FIG. 5 is a chart depicting example process conditions in accordance with an aspect of the invention.

### DETAILED DESCRIPTION

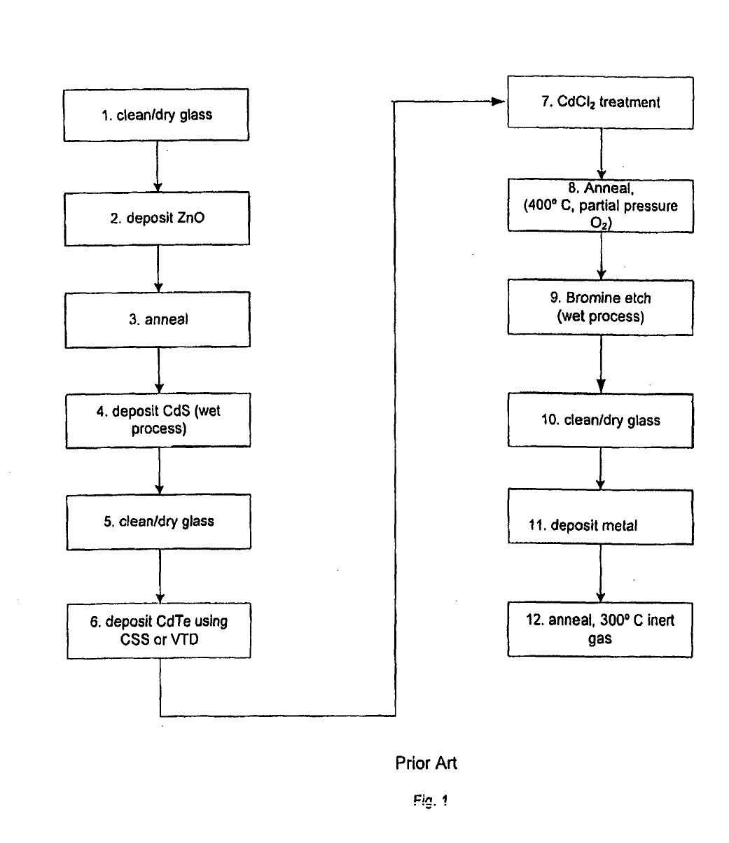

FIG. 1 shows a conventional method for creating a typical thin film CdTe photovoltaic device. In such a method there are at least three anneal steps and two wet process steps, resulting in undesirable complexity and long processing times. This can greatly increase the cost of a finished CdTe solar cell.

Referring to FIG. 1, the CdS layer is typically deposited in a wet process such as a chemical bath deposition method (CBD) or a close space sublimation (CSS) method. The thickness of the deposited layer usually is 50 to 200 nm. The CdS layer serves as a window layer and helps to reduce interface recombination with the subsequent CdTe layer.

After deposition of the CdTe layer, conventional processing technologies usually include a post deposition heat treatment with CdCl₂ that is annealed at 400° C. as shown. The CdCl₂ treatment has been shown to increase grain size.

A final step in the cell fabrication in the conventional process of FIG. 1 is the application of the electrical contact to the CdTe layer (shown as step 11, “deposit metal”). This comprises the back contact of the cell that is then annealed at 300° C. in an inert gas. Many different methods may be used for the back contact. However, it is recognized that this step is critical for CdTe cell performance and stability. As shown in FIG. 1, a conventional CdTe process uses a wet etch process to complete the metallization step.

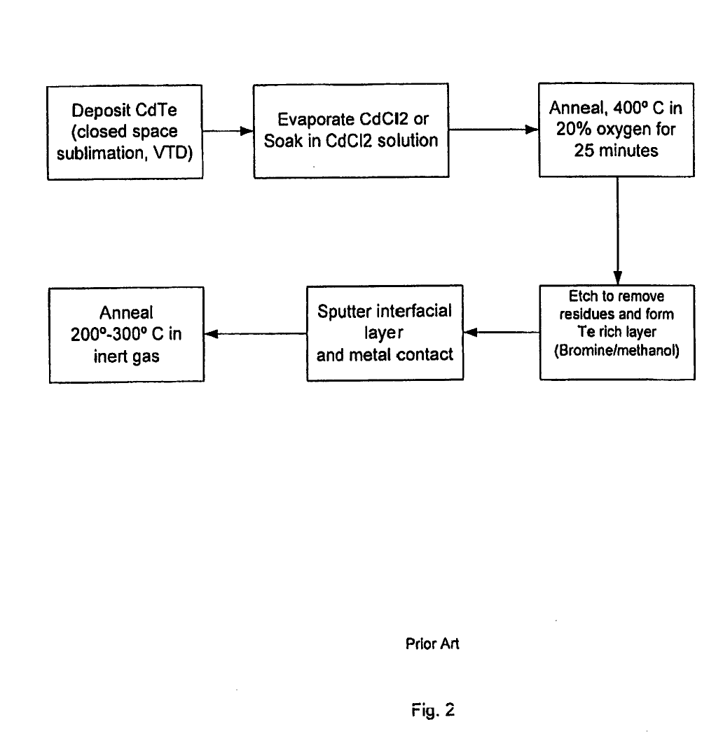

Referring to FIG. 2, CdTe is deposited by CSS or vapor transport deposition (VTD). CdCl₂ is then applied by evaporation or by soaking in a CdCl₂ solution. This is annealed at 400° C. in 20% oxygen for 25 minutes. An etchant such as bromine/methanol is then applied to remove residues and form a Te rich layer. Next, an interfacial layer and metal contact are sputtered onto the CdTe. This must be further annealed at 200-300° C. in an inert gas for about 25 minutes.

Such a conventional process uses a wet etch process (bromine/methanol) to remove residues and to form the Te layer. Such a wet process adds considerably to processing time and complexity, and requires expensive procedures for liquid waste removal.

A further disadvantage of forming the Te rich layer by a conventional wet process, such as shown in FIG. 2, is that it typically lacks sufficient control over the doping process to maintain a uniform thickness of the depletion region or depletion layer in the CdTe. This may lead to degradation of photovoltaic output over time.

It is desirable to maintain the presence of an electric field in the depletion region of the CdTe thin film to provide better photo current collection. Such a field separates photo generated holes and electrons and pulls the electrons toward the CdTe interface, thereby providing current through the cell. However, if the thickness of the depletion region in the CdTe is inadequate, a large portion of the electron-hole pairs generated in the region will have zero or a very small electric field. Such carriers may diffuse in opposite directions and recombine, thus not contributing to the photo current. This may result in undesirable shortened carrier lifetime and degradation of the CdTe solar cell.

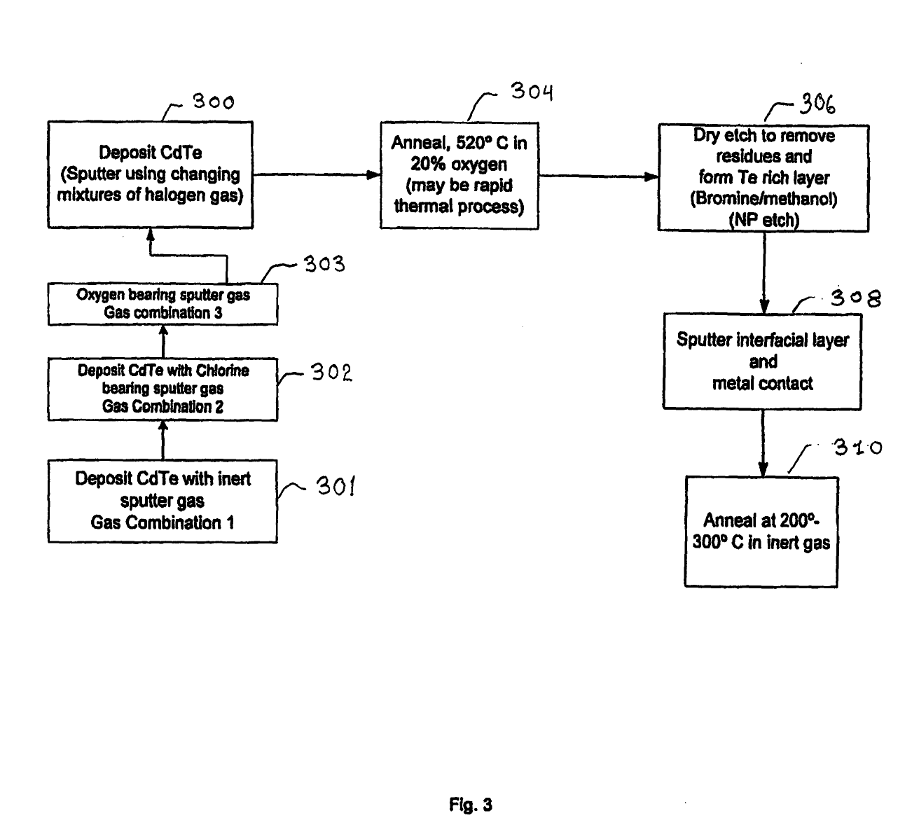

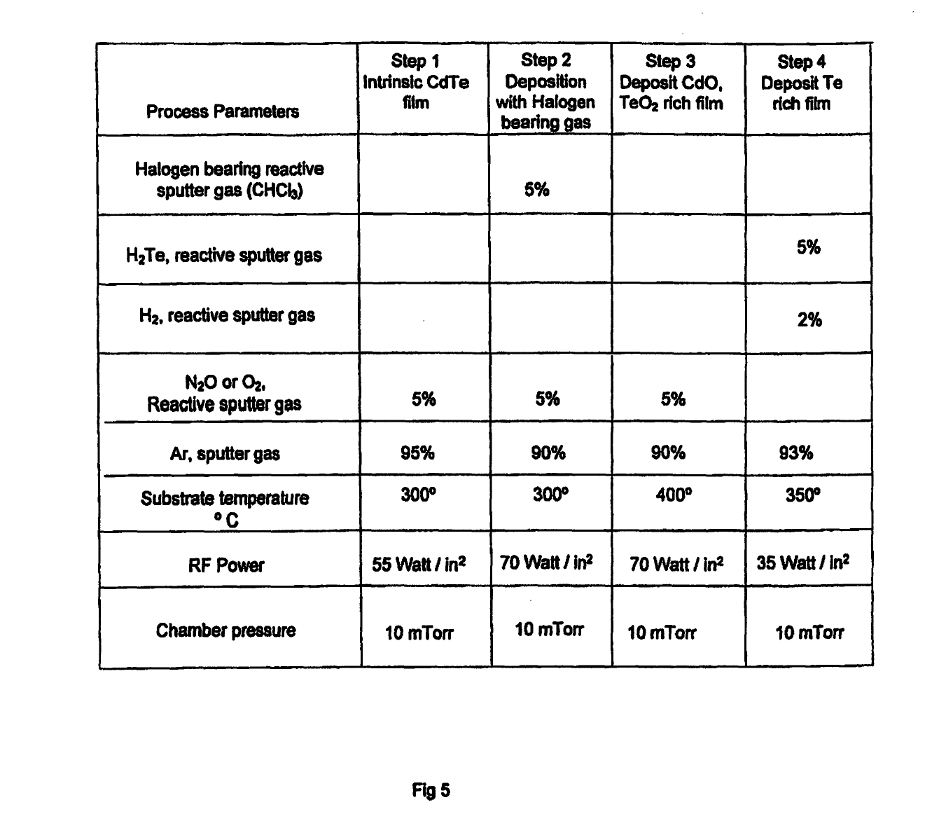

Referring generally to FIGS. 3 and 5, an improved process in accordance with features of the invention is described for making a CdTe thin film solar cell that overcomes the foregoing disadvantages inherent in conventional CdTe processing. An aspect of the invention provides for the elimination of wet process steps in forming a CdTe thin film solar cell, and employs a dry etch process after the CdTe deposition to provide the Te rich layer.

The CdTe film used in high efficiency solar panels contains chlorine and oxygen. An aspect of the invention provides a method of incorporating the required dopants during sputter deposition without subsequent wet etching steps.

The composition of the CdTe film can be changed and controllably adjusted due to the reactive chemistry of the gases used in the sputter deposition process. A halogen bearing sputter gas (such as chlorine) is used to dope the CdTe during film deposition, thereby to provide greater control over dopant density and profile in the CdTe layer. This achieves substantially precise, repeatable control over the definition of the depletion region in the CdTe film to provide enhanced carrier lifetime.

Also, oxygen can be added controllably to the CdTe layer in the presence of a plasma in the process chamber. RTP then is employed to avoid the conventional lengthy anneal step. This advantageously eliminates the thermal stress that is typically induced in the CdTe thin film by the annealing process and further enhances charge carrier lifetime as explained below. The foregoing aspects of the invention also avoid the need for wet treatments and significantly shorten the time, complexity, and costs of a CdTe thin film PV process.

Referring to FIGS. 3 and 5, in a first step 300, a CdTe layer is provided on a glass or other suitable substrate by sputtering, which is done under a controlled low pressure atmosphere condition. Refer to he table of process parameters shown in FIG. 5 t as a non limiting example. In the first step the reactive gas may be oxygen as at 303, which will react with the Cd and Te to form small amounts of Cd oxide and Te oxide in the deposited film.

In accordance with an aspect of the invention, a known amount of a halogen bearing gas, such as chlorine, is added to the controlled atmosphere of the process chamber at 302. For example, a means for measuring and metering a volumetric flow, such as a standard mass flow controller, is used to control precisely the amount of halogen in a sputter gas present in the atmosphere of the process chamber. The rate of deposition and total amount of material deposited can be measured by standard techniques such as, for example, by a laser thickness measurement meter. The deposition controller is calibrated to 5000 Å measured by a profilometer. It will be appreciated that this method is suitable for a continuous production line.

Once the base pressure is reached, the substrate is heated to a deposition rate of 0.2-0.3 Å/s initially, and gradually increased to 20 Å/s, and is allowed to stabilize.

In the first step 300 the halogen reactive gas will react with the Cd and Te to form Cd halide and Te halide. The effect of the halide increases the sputter rate of the CdTe, because the halide compounds are more easily removed from the CdTe target. Some of the halogen is incorporated into the deposited film in the form of Cd halide and Te halide. However, most of the halogen is present in the film as Cd halide, since the Te halides are characterized by a lower melting point and are more volatile.

Referring to the process parameters of FIG. 5, the CdTe is sputtered to a typical depth of 4 μm so that a p type layer is grown. Chlorine in the atmosphere of the sputter chamber is reactive with Cd, and a small amount of Cl will be incorporated into the deposited CdTe film. The amount of Cl incorporated into the film can be controlled by the partial pressure of Cl in the process/sputter chamber. The partial pressure of the chlorine in the sputter chamber can be adjusted during the deposition process so that the doping of the film is heavier or lighter as the film grows, thus providing an improved measure of control over the pn junction and dopant profile in the depletion region as compared to a conventional process.

Referring to FIG. 3, the deposition of CdTe by sputtering can be made in stages: a first stage 301, with inert sputter gas, then a second stage 302 with Cl (halogen) bearing sputter gas 302, and a third stage 303, made with oxygen bearing sputter gas The stages may not be limited to distinct boundaries, but rather the sputter as composition may change gradually during the deposition. The gas flow needs to be determined based on the pumping parameters of the deposition system. That is, as is well understood by one skilled in the art, the pumping rate, pressure, deposition rate and other parameters are highly dependent upon the geometry and size of the process chamber and other variables.

Next, an anneal process is made at 520° C. in 20 percent oxygen 304. This may be done using RTP, which greatly accelerates process time for a CdTe solar cell as compared to a conventional process. Oxygen may be controlled during the anneal process through a mass flow controller.

If the CdTe grain size is determined to be large enough by conventional profilometry techniques, such as scanning electron microscopy (SEM) or X-ray diffraction (XRD), it may not be necessary to activate the chlorine by a heat treatment. Cl previously has been incorporated in the CdTe layer during the sputter deposition.

The oxygen in the anneal also plays an important role in the formation of efficient CdTe films for solar cells. The anneal both improves the CdTe grain structure (making it much larger) and also increases the hole mobility and hole concentration.

In an alternative embodiment, the need for oxygen during the anneal step advantageously may be eliminated by introducing the oxygen into the CdTe film in the deposition chamber. Oxygen in a plasma is much more reactive than molecular oxygen.

A dry etch 306 can be used to remove residues and form the Te rich active layer. An interfacial layer (IFL) and metal contact are then provided by sputter deposition in accordance with techniques that are well known. A final anneal step 310 at 200-300 degrees C. takes place in an inert gas.

Thus, the net effect of the conventional device anneal, (400° C., 30 minutes or longer) could be accomplished much faster, in a rapid thermal process according to an aspect of the present invention, which is more suitable for in-line production of solar cells.

Due to the improved ability to control dopant concentration in accordance with an aspect of the present invention, the pn junction in CdTe can be more precisely defined and located so that it does not abut the thin film surface. Such improved control over the pn junction may reduce surface recombination and increase cell efficiency.

Elimination of the conventional anneal step (taking about 30 minutes or longer at 400 degrees C.) in accordance with an aspect of the invention may be particularly advantageous in that it would eliminate thermal stress and changes in the doping profile that otherwise may occur during a conventional anneal process. In thin film CdTe cells, it is critical that doping be uniform. In a conventional CdTe process, when dopant Profiles become non uniform, the depletion layer edge may migrate closer to the back contact interface resulting in degradation of the output current. Thermal stress induced by the conventional anneal step also may significantly change the carrier concentration magnitude and dopant profiles in the thin film CdTe layer thereby leading to degradation in charge carrier lifetime.

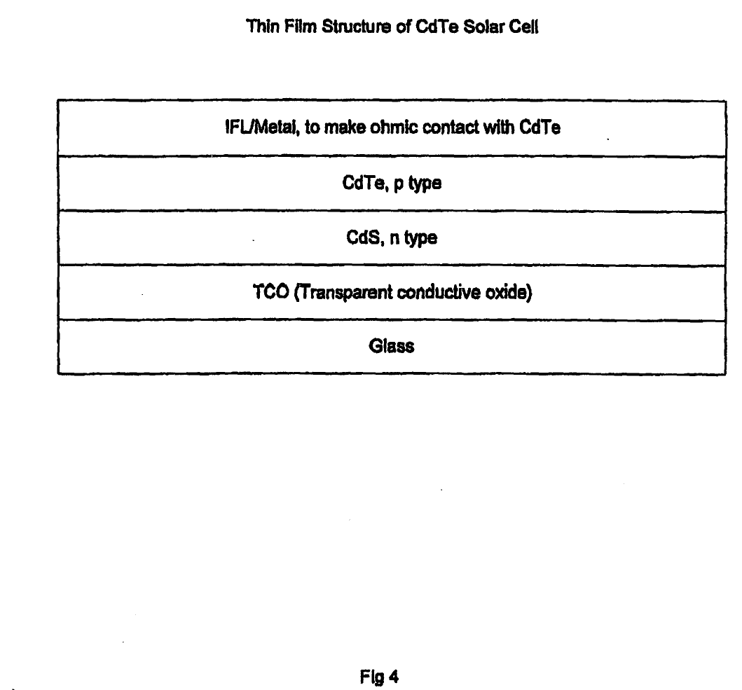

A representative structure of a CdTe solar cell made by the reduced process steps in accordance with features of the present invention is shown in FIG. 4. A substrate, such as glass provided with a TCO layer, is sputtered deposited with CdTe of CdS with a halogen bearing sputter gas such as chlorine as described above. This structure then may be annealed by a rapid thermal processing and nd dry etched to form the Te enriched layer. An IFL is then provided by sputtering to make ohmic contact with the CdTe. The rapid anneal and elimination of wet processing steps advantageously reducuce processing complexity and mitigate thermal stress in the layered structure of the final CdTe solar cell.

The foregoing features of the present invention provide improved control over dopant density and dopant profile of the depletion region. The invention also provides improved definition of the pn junction to prevent surface recombination and may make CdTe homo junction cells cost effective. Although CdTe can be doped both p and n type, CdTe homo junction cells typically have not shown very high efficiency. Due to the high absorption coefficient of CdTe and small diffusion length, the pn junction must be formed close to the surface which thereby reduces carrier lifetime through surface recombination. The present invention is believed to overcome these shortcomings.

While the invention has been described in connection with what are presently considered to be the most practical and preferred embodiments, it is to be understood that the invention is not limited to the disclosed embodiments and alternatives as set forth above, but on the contrary is intended to cover various modifications and equivalent arrangements.

Therefore, persons of ordinary skill in this field are to understand that all such equivalent arrangements and modifications are to be included within the scope of the following claims.

We claim:

1. A process for producing a thin film CdTe photovoltaic device comprising:
depositing, with a sputter gas, a CdTe layer on a substrate in a process chamber;
adding varying amounts of halogen to the sputter gas for controlling the deposition rate and/or thickness of the CdTe layer;
annealing the deposited CdTe layer;
dry etching the CdTe layer to form a Te rich active layer;
providing an interfacial layer and metal contact adjacent the active layer to complete the photovoltaic device.

2. A process according to claim 1, wherein the CdTe layer is deposited with an inert sputter gas.

3. A process according to claim 1, wherein the CdTe layer is deposited with a chlorine bearing sputter gas.

4. A process according to claim 1, wherein the CdTe layer is deposited using an oxygen bearing sputter gas.

5. A process according to claim 1, wherein the deposited CdTe layer is annealed by a rapid thermal process at about 520° C. in an atmosphere containing about 20% oxygen;

6. A process according to claim 1, further comprising the step of dry etching the annealed CdTe layer to remove residues and form the CdTe rich active layer;

7. A process according to claim 1, further comprising adjusting partial pressure of the halogen bearing gas in the process chamber such that doping of the CdTe film is heavier or lighter as the film grows for improved control of dopant profile in a depletion region.

8. A CdTe thin film photovoltaic device made by the process comprising:
depositing a CdTe layer on a substrate in a process chamber with a sputter gas;
adding predetermined amounts of halogen to the sputter gas for controlling the deposition rate and/or thickness of the CdTe layer;
annealing the deposited CdTe layer in an atmosphere containing at least 20 percent oxygen at about 520° C. by rapid thermal processing;
dry etching the CdTe layer to form a Te rich active layer;
providing an interfacial layer and metal contact adjacent the active layer.
